(19) United States
(12) Patent Application Publication
(10) Pub. No.: US 2022/0131018 A1
(43) Pub. Date: Apr. 28, 2022

(54) FINGERPRINT SENSOR AND DISPLAY DEVICE INCLUDING THE SAME

(71) Applicant: Samsung Display Co., Ltd., Yongin-si (KR)

(72) Inventor: Woo Seok JEON, Seoul (KR)

(21) Appl. No.: 17/447,043

(22) Filed: Sep. 7, 2021

(30) Foreign Application Priority Data
Oct. 26, 2020 (KR) 10-2020-0139102

(51) Int. Cl. H01L 31/0216; H01L 27/32; H01L 31/105; G06K 9/00

(52) U.S. Cl. CPC H01L 31/02164; G06K 9/0004; H01L 31/105; H01L 27/3227

(57) ABSTRACT

A fingerprint sensor, includes: a light sensing layer including a photo-sensing element to flow a sensing current according to incident light; and a collimator layer on the light sensing layer, the collimator layer including: a first light blocking layer having a plurality of first holes; a first light transmitting layer on the first light blocking layer; and a second light blocking layer on the first light transmitting layer, and having a plurality of second holes overlapping with the plurality of first holes.

### CROSS-REFERENCE TO RELATED APPLICATION

This application claims priority to and the benefit of Korean Patent Application No. 10-2020-0139102, filed on Oct. 26, 2020, in the Korean Intellectual Property Office, the disclosure of which is incorporated herein by reference in its entirety.

### BACKGROUND

### 1. Field

Aspects of one or more embodiments of the present disclosure relate to a fingerprint sensor, and a display device including the fingerprint sensor.

### 2. Description of the Related Art

A display device is applied to various electronic appliances, for example, such as smart phones, tablet PCs, notebook computers, monitors, and televisions (TVs). Recently, due to the development of mobile communication technology, the use of portable electronic appliances, for example, such as smart phones, tablets, and notebook computers, has greatly increased. Privacy information such as contacts, call history, messages, photos, memos, user's web surfing information, user's location information, and financial information are stored in the portable electronic appliances. Therefore, in order to protect personal information of the portable electronic appliances, fingerprint authentication for authenticating a fingerprint, which is a user's biometric information, may be used. In this case, the display device may include a fingerprint sensor for the fingerprint authentication. The fingerprint sensor may be implemented as an optical type, an ultrasonic type, or a capacitive type. The optical type fingerprint sensor may include a collimator having a light sensing portion for sensing light, openings for providing light to the light sensing portion, and a light blocking portion for blocking light.

The above information disclosed in this Background section is for enhancement of understanding of the background of the present disclosure, and therefore, it may contain information that does not constitute prior art.

### SUMMARY

When a fingerprint sensor is disposed at (e.g., in or on) a bezel area or a non-display area of a display device, there may be a limit in increasing (e.g., in widening) the display area of the display device. Therefore, recently, the fingerprint sensor may be disposed at (e.g., in or on) the display area of the display device. In this case, because the fingerprint sensor is disposed under (e.g., underneath) the display panel, the amount of light incident on the light sensing unit of the fingerprint sensor may be small (e.g., may be decreased). However, if the area of the light blocking portion of the collimator is decreased in order to increase the amount of light incident on the light sensing portion of the fingerprint sensor, noise light that is incident on the light sensing portion may increase. In this case, the fingerprint recognition accuracy may be lowered.

One or more embodiments of the present disclosure are directed to a fingerprint sensor capable of improving transmittance of a collimator, and reducing noise light. One or more embodiments of the present disclosure are directed to a display device including the fingerprint sensor.

However, the aspects and features of the present disclosure are not limited to the ones set forth herein. The above and other aspects and features of the present disclosure will become more apparent to one of ordinary skill in the art to which the present disclosure pertains by referencing the detailed description of the present disclosure given below with reference to the figures.

According to one or more embodiments of the present disclosure, a fingerprint sensor, includes: a light sensing layer including a photo-sensing element configured to flow a sensing current according to incident light; and a collimator layer on the light sensing layer, the collimator layer including: a first light blocking layer having a plurality of first holes; a first light transmitting layer on the first light blocking layer; and a second light blocking layer on the first light transmitting layer, and having a plurality of second holes overlapping with the plurality of first holes.

In an embodiment, the first light transmitting layer may fill the plurality of first holes, and may cover the first light blocking layer.

In an embodiment, the first light blocking layer may have a single-layer structure or a multi-layered structure.

In an embodiment, the first light blocking layer may have the single-layer structure, and may include a black matrix or amorphous carbon.

In an embodiment, the first light blocking layer may have the multi-layer structure, and may include a metal layer and a metal oxide layer that are stacked on one another.

In an embodiment, the first light blocking layer may have the multi-layer structure, and may include a plurality of oxide layers having different refractive indices from one another that are alternately stacked with each other.

In an embodiment, the plurality of oxide layers may have a stacked structure of silicon oxide and silicon nitride, or a stacked structure of silicon oxide and titanium oxide.

In an embodiment, the first light blocking layer may include a moth eye structure on at least one surface thereof.

In an embodiment, each of the first light blocking layer and the second light blocking layer may include a metal.

In an embodiment, the fingerprint sensor may further include: a first antireflection layer between the first light blocking layer and the first light transmitting layer.

In an embodiment, the first antireflection layer may contact at least one of an upper surface or a side surface of the first light blocking layer.

In an embodiment, the fingerprint sensor may further include: a second antireflection layer between the first light transmitting layer and the second light blocking layer.

In an embodiment, the second antireflection layer may contact a lower surface of the second light blocking layer and the first light transmitting layer.

According to one or more embodiments of the present disclosure, a fingerprint sensor includes: a light sensing layer including a photo-sensing element configured to flow a sensing current according to incident light; and a collimator layer on the light sensing layer, the collimator layer including: a first light blocking layer having a plurality of first holes; a first light transmitting layer on the first light blocking layer; a second light blocking layer on the first light transmitting layer, and having a plurality of second holes overlapping with the plurality of first holes; a second light transmitting layer on the second light blocking layer; and a third light blocking layer on the second light transmitting layer, and having a plurality of third holes overlapping with the plurality of second holes.

In an embodiment, the first light transmitting layer may fill the plurality of first holes, and may be located on the first light blocking layer, and the second light transmitting layer may fill the plurality of second holes, and may be located on the second light blocking layer.

In an embodiment, the first light blocking layer may have a single-layer structure, and may include a black matrix or amorphous carbon.

In an embodiment, the first light blocking layer may have a single-layer structure, and may include a moth eye structure on at least one surface thereof.

In an embodiment, the first light blocking layer may have a multi-layered structure, and the first light blocking layer may include a metal layer and a metal oxide layer that are stacked on one another, or a plurality of oxide layers having different refractive indices from one another that are alternately stacked with each other.

According to one or more embodiments of the present disclosure, a display device, includes: a display panel configured to display an image; and a fingerprint sensor on a surface of the display panel, and configured to sense light passed through the display panel. The fingerprint sensor includes: a light sensing layer including a photo-sensing element configured to flow a sensing current according to incident light; and a collimator layer on the light sensing layer. The collimator layer includes: a first light blocking layer having a plurality of first holes; a first light transmitting layer on the first light blocking layer; and a second light blocking layer on the first light transmitting layer, and having a plurality of second holes overlapping with the plurality of first holes.

In an embodiment, the photo-sensing element may include: a first sensing electrode; a sensing semiconductor layer on the first sensing electrode, and including an N-type semiconductor layer, an I-type semiconductor layer, and a P-type semiconductor layer; and a second sensing electrode on the sensing semiconductor layer.

### BRIEF DESCRIPTION OF THE DRAWINGS

The above and other aspects and features of the present disclosure will be more clearly understood from the following detailed description of the illustrative, non-limiting example embodiments with reference to the accompanying drawings, in which:

FIG. 1 is a perspective view of a display device according to an embodiment;

FIG. 2 is a perspective view illustrating the fingerprint sensor of FIG. 1;

FIG. 3 is a cross-sectional view illustrating an example of the display panel and the fingerprint sensor taken along the line I-I of FIG. 1;

FIG. 4 is an enlarged cross-sectional view illustrating an example of the display panel of FIG. 3;

FIG. 5 is a cross-sectional view illustrating an example of a fingerprint sensor according to an embodiment;

FIG. 6 is a cross-sectional view illustrating another example of a fingerprint sensor according to an embodiment;

FIG. 7 is a cross-sectional view illustrating an example of a first light blocking layer of a fingerprint sensor according to an embodiment;

FIG. 8 is a cross-sectional view illustrating another example of a first light blocking layer of a fingerprint sensor according to an embodiment;

FIG. 9 is a cross-sectional view illustrating an example of a fingerprint sensor according to another embodiment;

FIG. 10 is a cross-sectional view illustrating another example of a fingerprint sensor according to another embodiment;

FIG. 11 is a cross-sectional view illustrating an example of a fingerprint sensor according to another embodiment;

FIGS. 12-16 are cross-sectional views illustrating various processes of a method of manufacturing the fingerprint sensor of FIG. 9;

FIG. 17 is a cross-sectional view illustrating another example of a method of manufacturing the fingerprint sensor of FIG. 9; and

FIGS. 18-23 are cross-sectional views illustrating various processes of a method of manufacturing a fingerprint sensor according to another embodiment.

### DETAILED DESCRIPTION

Hereinafter, example embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, descriptions thereof may not be repeated.

When a certain embodiment may be implemented differently, a specific process order may be different from the described order. For example, two consecutively described processes may be performed at the same or substantially at the same time, or may be performed in an order opposite to the described order.

Each of the features of the various embodiments of the present disclosure may be used singularly or may be combined with each other, in part or in whole, and technically various interlocking and driving are possible. Each embodiment may be implemented independently of each other, or may be implemented together in an association with each other, unless otherwise specified.

In the drawings, the relative sizes of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

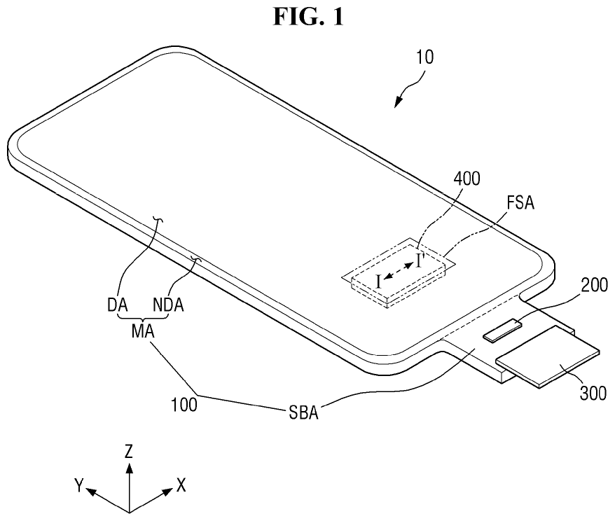

FIG. 1 is a perspective view of a display device according to an embodiment.

Referring to FIG. 1, a display device 10, which is a device for displaying a moving image and/or a still image, may be used as a display screen of various suitable products, for example, such as televisions, notebooks, monitors, billboards, internet of things (IOTs) devices, and/or the like, as well as for various suitable portable electronic appliances, for example, such as mobile phones, smart phones, tablet personal computers (tablet PCs), smart watches, watch phones, mobile communication terminals, electronic notebooks, electronic books, portable multimedia players (PMPs), navigators, ultra-mobile PCs (UMPCs), and/or the like.

The display device 10 may be a light emitting display device, for example, such as an organic light emitting display device that uses an organic light emitting diode, a quantum dot light emitting display device including a quantum dot light emitting layer, an inorganic light emitting display device that uses an inorganic semiconductor, or a micro light emitting display device that uses a micro light emitting diode (LED). Hereinafter, for convenience of description, the display device 10 will be described in more detail as an organic light emitting display device, but the present disclosure is not limited thereto.

The display device 10 includes a display panel 100, a display driving circuit 200, a circuit board 300, and a fingerprint sensor 400.

The display panel 100 may have a rectangular planar shape having short sides extending in a first direction (e.g., the X-axis direction), and long sides extending in a second direction (e.g., the Y-axis direction) crossing the first direction (e.g., the X-axis direction). A corner where a short side extending in the first direction (X-axis direction) meets a long side extending in the second direction (Y-axis direction) may be formed to have a rounded shape with a suitable curvature (e.g., a predetermined curvature), or may have a right-angled shape. The planar shape of the display panel 100 is not limited to the rectangular shape, and the display panel 100 may be formed in various suitable planar shapes, for example, such as another polygonal shape, a circular shape, or an elliptical shape. The display panel 100 may be formed to be flat or substantially flat, but the present disclosure is not limited thereto. For example, the display panel 100 may include a curved portion formed at left and right ends (e.g., left and right sides) thereof, and the curved portion may have a constant or substantially constant curvature, or a variable curvature. In addition, the display panel 100 may be flexible, such that the display panel 100 may be bent, warped, folded, and/or rolled.

The display panel 100 may include a main area MA, and a sub-area SBA.

The main area MA may include a display area DA for displaying an image, and a non-display area NDA that is a peripheral area of the display area DA. The display area DA may include a plurality of display pixels for displaying the image. The non-display area NDA may be defined as an area extending from the outside of the display area DA to an edge of the display panel 100. For example, the non-display area NDA may at least partially surround (e.g., around a periphery of) the display area DA.

The display area DA may include a fingerprint sensing area FSA. The fingerprint sensing area FSA refers to an area at (e.g., in or on) which the fingerprint sensor 400 is disposed. The fingerprint sensing area FSA may be a portion of the display area DA as shown in FIG. 1, but the present disclosure is not limited thereto. For example, in some embodiments, the fingerprint sensing area FSA may correspond to (e.g., may extend across) the entire area of the display area DA, and may be the same or substantially the same as the display area DA.

The sub area SBA may protrude (e.g., may extend) from one side (e.g., from one end) of the main area MA in the second direction (Y-axis direction). The length of the sub-area SBA in the first direction (X-axis direction) may be smaller than the length of the main region MA in the first direction (X-axis direction), and the length of the sub-area SBA in the second direction (Y-axis direction) may be smaller than the length of the main area MA in the second direction (Y-axis direction), but the present disclosure is not limited thereto.

Although FIG. 1 shows that the sub-area SBA is unfolded (e.g., unbent), the sub-area SBA may be bent, and in this case, the sub-area SBA may be disposed on a lower surface (e.g., on a rear surface) of the display panel 100. When the sub-area SBA is bent, the sub-area SBA may overlap with the main area MA in a thickness direction (e.g., the Z-axis direction) of a substrate SUB. The display driving circuit 200 may be disposed at (e.g., in or on) the sub-area SBA.

The display driving circuit 200 outputs signals and voltages for driving the display panel 100. The display driving circuit 200 may be formed as an integrated circuit (IC), and may attached onto the display panel 100 by a chip on glass (COG) method, a chip on plastic (COP) method, or an ultrasonic bonding method. However, the present disclosure is not limited thereto. For example, the display driving circuit 200 may be attached onto the circuit board 300 by a chip on film (COF) method.

The circuit board 300 may be attached onto one end of the sub-area SBA of the display panel 100 using an anisotropic conductive film. Thus, the circuit board 300 may be electrically connected to the display panel 100 and the display driving circuit 200. The display panel 100 and the display driving circuit 200 may receive digital video data, timing signals, and driving voltages through the circuit board 300. The circuit board 300 may be a flexible printed circuit board, a printed circuit board, or a flexible film, for example, such as a chip on film.

The fingerprint sensor 400 may be disposed on the lower surface (e.g., the rear surface) of the display panel 100. The fingerprint sensor 400 may be attached to the lower surface of the display panel 100 using a transparent adhesive member. For example, the transparent adhesive member may be a transparent adhesive film, for example, such as an optically clear adhesive (OCA) film, or a transparent adhesive resin, for example, such as an optically clear resin (OCR).

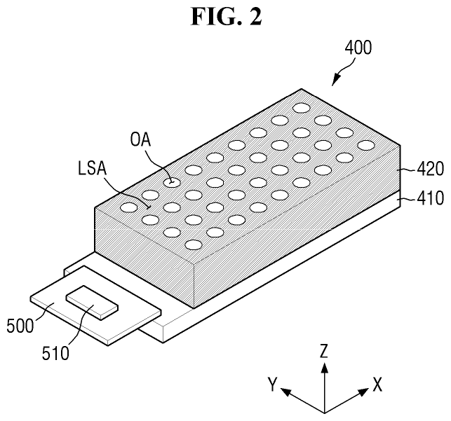

FIG. 2 is a perspective view illustrating the fingerprint sensor of FIG. 1.

Referring to FIG. 2, the fingerprint sensor 400 may include a fingerprint sensing layer 410, and a collimator layer 420.

The fingerprint sensing layer 410 may include a plurality of sensor pixels arranged along the first direction (X-axis direction) and the second direction (Y-axis direction). Each of the sensor pixels may include a photo-sensing element through which a sensing current may flow according to the incident light, at least one transistor connected to the photo-sensing element, and at least one capacitor connected to the photo-sensing element and/or the transistor. The photo-sensing element may include (e.g., may be) a photo diode or a photo transistor.

The collimator layer 420 may be disposed on the fingerprint sensing layer 410. The collimator layer 420 may include openings OA arranged along the first direction (X-axis direction) and the second direction (Y-axis direction), and a light blocking portion LSA disposed between the openings OA. Each of the openings OA may transmit light, and the light blocking portion LSA may block light. Each of the openings OA may have a circular planar shape as shown in FIG. 2, but the shape of the openings OA is not limited thereto. For example, each of the openings OA may have an elliptical planar shape, or a polygonal planar shape.

A fingerprint circuit board 500 may be disposed on a portion of the fingerprint sensing layer 410 that is not covered by the collimator layer 420. The fingerprint circuit board 500 may be attached to an upper surface of the fingerprint sensing layer 410 that is not covered by the collimator layer 420 using an anisotropic conductive film. Thus, the fingerprint circuit board 500 may be electrically connected to the sensor pixels of the fingerprint sensing layer 410. Therefore, each of the sensor pixels of the fingerprint sensing layer 410 may output a sensing voltage according to the sensing current of the photo-sensing element through the fingerprint circuit board 500. A fingerprint driving circuit 510 may be electrically connected to the fingerprint circuit board 500, and may recognize a fingerprint pattern of a finger according to the sensing voltages of the sensor pixels.

The fingerprint driving circuit 510 may be disposed on the fingerprint circuit board 500 as shown in FIG. 2, but the present disclosure is not limited thereto. For example, the fingerprint driving circuit 510 may be disposed on a separate circuit board that is electrically connected to the fingerprint circuit board 500. The fingerprint circuit board 500 may be a flexible printed circuit board, a printed circuit board, or a flexible film, for example, such as a chip-on film.

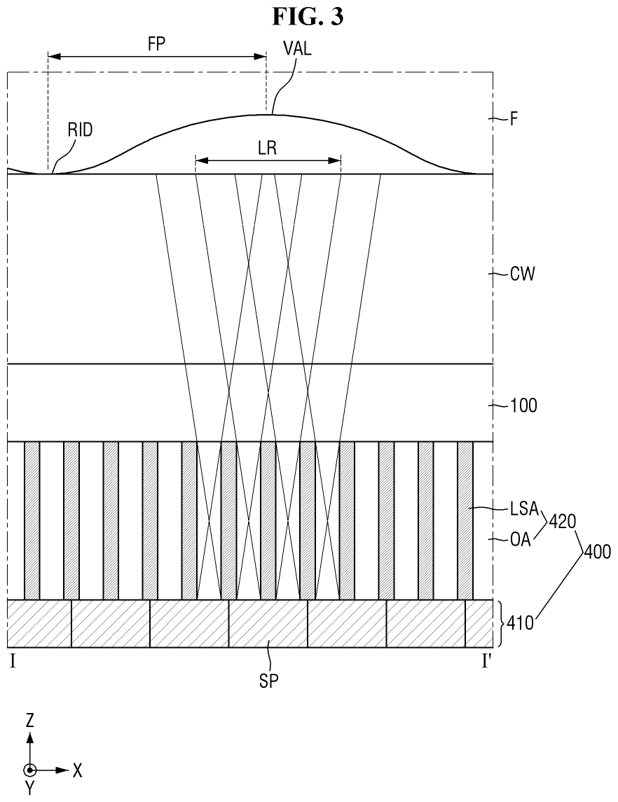

FIG. 3 is a cross-sectional view illustrating an example of the display panel and the fingerprint sensor taken along the line I-I of FIG. 1. FIG. 3 illustrates that a finger F of a user is on (e.g., is placed on or touches) the display device 10 to recognize a fingerprint thereof.

Referring to FIG. 3, the display device 10 further includes a cover window CW disposed on the upper surface of the display panel 100. The cover window CW may be disposed on the display panel 100 to cover the upper surface of the display panel 100. The cover window CW may serve to protect the upper surface of the display panel 100. The cover window CW may be attached to the upper surface of the display panel 100 using a transparent adhesive member.

The cover window CW includes (e.g., is made of) a transparent material, for example, such as glass or plastic. For example, when the cover window CW includes (e.g., is made of) glass, the cover window CW may be an ultra-thin glass UTG having a thickness of 0.1 mm or less. When the cover window CW includes (e.g., is made of) plastic, the cover window CW may be a transparent polyimide film.

The fingerprint sensor 400 may be disposed on the lower surface (e.g., the rear surface) of the display panel 100. The fingerprint sensor 400 may be attached to the lower surface of the display panel 100 using a transparent adhesive member.

The fingerprint sensor 400 includes a fingerprint sensing layer 410 including a plurality of sensor pixels SP, and a collimator layer 420. The collimator layer 420 may include the openings OA, and the light blocking portion LSA disposed between the openings OA. Each of the sensor pixels SP may overlap with a plurality of the openings OA from among the openings OA of the collimator layer 420 in the third direction (e.g., the Z-axis direction).

Each of the openings OA of the collimator layer 420 may be a path through which light reflected from a ridge RID and a valley VAL of the fingerprint of the finger F is incident. In more detail, when the user's finger F comes into contact with the cover window CW, light output from the display panel 100 may be reflected from the ridge RID and the valley VAL of the fingerprint of the finger F. The light reflected by the finger F may be incident on the sensor pixels SP of the fingerprint sensing layer 410 through the display panel 100 and the openings OA of the collimator layer 420.

A range LR of the light incident on the sensor pixel SP through the openings OA of the collimator layer 420 may be shorter than a distance FP between the ridge RID and the valley VAL of the fingerprint of the finger F. The distance FP between the ridge RID and the valley VAL of the fingerprint of the finger F may be about 500 μm. Thus, the sensing currents flowing through the photo-sensing elements of the sensor pixels SP may be different from each other depending on the light reflected from the ridge RID of the fingerprint of the finger F and the light reflected from the valley VAL of the fingerprint of the finger F. Therefore, the sensing voltages output from the sensor pixels SP may also be different from each other depending on the light reflected from the ridge RID of the fingerprint of the finger F and the light reflected from the valley VAL of the fingerprint of the finger F. Accordingly, the fingerprint driving circuit 510 may recognize a fingerprint pattern of the finger F depending on the sensing voltages of the sensor pixels SP.

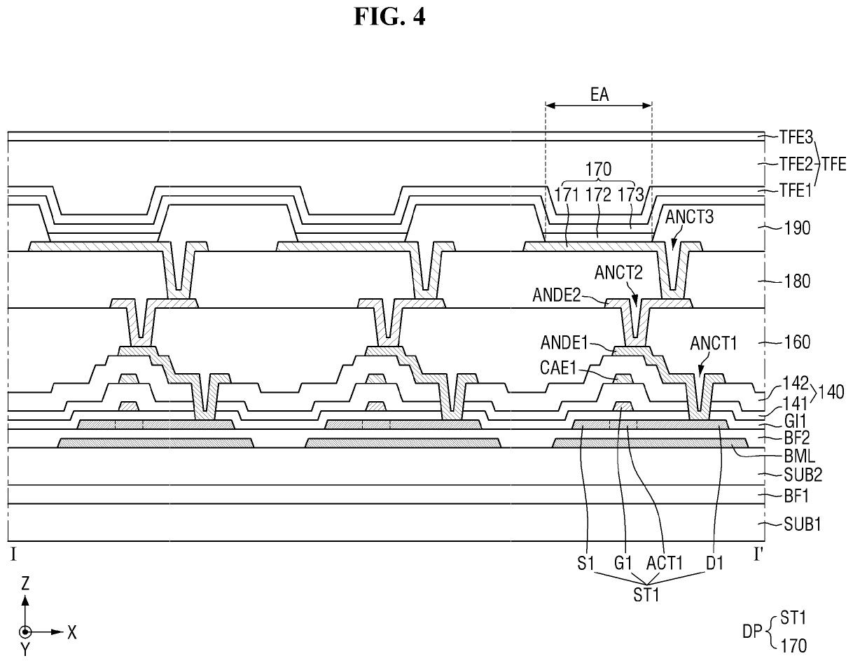

FIG. 4 is an enlarged cross-sectional view illustrating an example of the display panel of FIG. 3.

Referring to FIG. 4, the display panel 100 may include a plurality of display pixels DP that display an image. Each of the display pixels DP may include a first thin film transistor ST1, and a light emitting element 170.

A first buffer layer BF1 may be disposed on a first substrate SUB1, a second substrate SUB2 may be disposed on the first buffer layer BF1, and a second buffer layer BF2 may be disposed on the second substrate SUB2.

Each of the first substrate SUB1 and the second substrate SUB2 may include (e.g., may be made of) an insulating material, for example, such as a polymer resin. For example, each of the first substrate SUB1 and the second substrate SUB2 may include polyimide. Each of the first substrate SUB1 and the second substrate SUB2 may be a flexible substrate capable of being bent, folded, rolled, and/or the like.

Each of the first buffer layer BF1 and the second buffer layer BF2 may be a layer for protecting the thin film transistor ST1 and a light emitting layer 172 of the light emitting element 170 from moisture that may penetrate through the first substrate SUB1 and the second substrate SUB2, which may be vulnerable to moisture permeation. Each of the first buffer layer BF1 and the second buffer layer BF2 may be formed of a plurality of inorganic layers that are alternately stacked. For example, each of the first buffer layer BF1 and the second buffer layer BF2 may be formed to have a multi-layered structure in which two or more inorganic layers from among a silicon nitride layer, a silicon oxynitride layer, a silicon oxide layer, a titanium oxide layer, and/or an aluminum oxide layer are alternatively stacked.

A light blocking layer BML may be disposed on the second substrate SUB2 between the second substrate SUB2 and the second buffer layer BF2. The light blocking layer BML may be disposed to overlap with a first active layer ACT1 of the first thin film transistor ST1 in the third direction (Z-axis direction), in order to prevent or substantially prevent a leakage current from occurring when light is incident on the first active layer ACT1 of the first thin film transistor ST1. The light blocking layer BML may be formed as a single layer or as multiple layers, including any suitable one or more of molybdenum (Mo), aluminum (Al), chromium (Cr), gold (Au), titanium (Ti), nickel (Ni), neodymium (Nd), copper (Cu), and/or an alloy thereof.

The first active layer ACT1 of the first thin film transistor ST1 may be disposed on the second buffer layer BF2. The first active layer ACT1 of the first thin film transistor ST1 may include polycrystalline silicon, single crystal silicon, low-temperature polycrystalline silicon, amorphous silicon, or an oxide semiconductor. Because the first active layer ACT1 of the first thin film transistor ST1, which may be exposed without being covered by a first gate insulating layer GI1, is doped with impurities or ions, the first active layer ACT1 may have a conductivity. Conductive regions of the first active layer ACT1 may be formed into a first source electrode S1 and a first drain electrode D1 of the first thin film transistor ST1.

The first gate insulating layer GI1 may be disposed on the first active layer ACT1 of the first thin film transistor ST1. Although FIG. 4 shows that the first gate insulating layer GI1 is disposed between a first gate electrode G1 and the first active layer ACT1 of the first thin film transistor ST1, the present disclosure is not limited thereto. For example, the first gate insulating layer GI1 may be disposed between a first interlayer insulating layer 141 and the first active layer ACT1, and/or between the first interlayer insulating layer 141 and the second buffer layer BF2. The first gate insulating layer GI1 may be formed of an inorganic layer, for example, such as a silicon nitride layer, a silicon oxynitride layer, a silicon oxide layer, a titanium oxide layer, or an aluminum oxide layer.

The first gate electrode G1 of the first thin film transistor ST1 may be disposed on the first gate insulating layer GI1. The first gate electrode G1 of the first thin film transistor ST1 may overlap with the first active layer ACT1 in the third direction (Z-axis direction). The first gate electrode G1 of the first thin film transistor ST1 may be formed as a single layer or as multiple layers, including any suitable one or more of molybdenum (Mo), aluminum (Al), chromium (Cr), gold (Au), titanium (Ti), nickel (Ni), neodymium (Nd), copper (Cu), and/or an alloy thereof.

Although FIG. 4 shows that the first thin film transistor ST1 is formed in a top gate structure in which the first gate electrode G1 is located over (e.g., above) the first active layer ACT1, the present disclosure is not limited thereto. For example, the first thin film transistor ST1 may be formed in a bottom gate structure in which the first gate electrode G1 is located under (e.g., underneath) the first active layer ACT1, or may be formed in a double gate structure in which the first gate electrode G1 is located both over the first active layer ACT1 and under the first active layer ACT1.

The first interlayer insulating layer 141 may be disposed on the first gate electrode G1 of the first thin film transistor ST1. The first interlayer insulating layer 141 may be formed of an inorganic layer, for example, such as a silicon nitride layer, a silicon oxynitride layer, a silicon oxide layer, a titanium oxide layer, or an aluminum oxide layer. The first interlayer insulating layer 141 may include a plurality of inorganic layers.

A first capacitor electrode CAE1 may be disposed on the first interlayer insulating layer 141. The first capacitor electrode CAE1 may overlap with the first gate electrode G1 of the first thin film transistor ST1 in the third direction (Z-axis direction). Because the first interlayer insulating film 141 may have a suitable dielectric constant (e.g., a predetermined dielectric constant), a capacitor may be formed by the first capacitor electrode CAE1, the first gate electrode G1, and the first interlayer insulating layer 141 disposed between the first capacitor electrode CAE1 and the first gate electrode G1. The first capacitor electrode CAE1 may be formed as a single layer or as multiple layers, including any suitable one or more of molybdenum (Mo), aluminum (Al), chromium (Cr), gold (Au), titanium (Ti), nickel (Ni), neodymium (Nd), copper (Cu), and/or an alloy thereof.

A second interlayer insulating layer 142 may be disposed on the first capacitor electrode CAE1. The second interlayer insulating layer 142 may be formed of an inorganic layer, for example, such as a silicon nitride layer, a silicon oxynitride layer, a silicon oxide layer, a titanium oxide layer, or an aluminum oxide layer. The second interlayer insulating layer 142 may include a plurality of inorganic layers.

A first anode connection electrode ANDE1 may be disposed on the second interlayer insulating layer 142. The first anode connection electrode ANDE1 may be connected to the first drain electrode D1 of the first thin film transistor ST1 through a first anode contact hole ANCT1 that penetrates the first interlayer insulating layer 141 and the second interlayer insulating layer 142 to expose the first drain electrode D1 of the first thin film transistor ST1. The first anode connection electrode ANDE1 may be formed as a single layer or as multiple layers, including any suitable one or more of molybdenum (Mo), aluminum (Al), chromium (Cr), gold (Au), titanium (Ti), nickel (Ni), neodymium (Nd), copper (Cu), and/or an alloy thereof.

A first organic layer 160 for planarization may be disposed on the first anode connection electrode ANDE1. The first organic layer 160 may be formed of an organic material, for example, such as acrylic resin, epoxy resin, phenolic resin, polyamide resin, or polyimide resin.

A second anode connection electrode ANDE2 may be disposed on the first organic layer 160. The second anode connection electrode ANDE2 may be connected to the first anode connection electrode ANDE1 through a second anode contact hole ANCT2 that penetrates the first organic layer 160 to expose the first anode connection electrode ANDE1. The second anode connection electrode ANDE2 may be formed as a single layer or as multiple layers, including any suitable one or more of molybdenum (Mo), aluminum (Al), chromium (Cr), gold (Au), titanium (Ti), nickel (Ni), neodymium (Nd), copper (Cu), and/or an alloy thereof.

A second organic layer 180 may be disposed on the second anode connection electrode ANDE2. The second organic layer 180 may be formed of an organic material, for example, such as acrylic resin, epoxy resin, phenolic resin, polyamide resin, or polyimide resin.

The light emitting elements 170 and a bank (e.g., a bank layer) 190 may be disposed on the second organic layer 180. Each of the light emitting elements 170 may include a first emission electrode 171, a light emitting layer 172, and a second emission electrode 173.

The first emission electrode 171 may be formed on the second organic layer 180. The first emission electrode 171 may be connected to the second anode connection electrode ANDE2 through a third anode contact hole ANCT3 that penetrates the second organic layer 180 to expose the second anode connection electrode ANDE2.

In a top emission structure in which light is emitted in a direction towards the second emission electrode 173 based on the light emitting layer 172, the first emission electrode 171 may be formed of a metal material having a high reflectance, for example, such as a stacked structure of aluminum and titanium (e.g., Ti/Al/Ti), a stacked structure of aluminum and ITO (e.g., ITO/Al/ITO), an APC alloy, or a stacked structure of an APC alloy and ITO (e.g., ITO/APC/ITO). The APC alloy may include (e.g., may be) an alloy of silver (Ag), palladium (Pd), and copper (Cu).

The bank 190 may be formed to partition the first emission electrode 171 on the second organic layer 180 in order to define a light emission area EA. The bank 190 may be formed to cover an edge of the first emission electrode 171. The bank 190 may be formed of an organic material, for example, such as acrylic resin, epoxy resin, phenolic resin, polyamide resin, or polyimide resin.

The light emission area EA refers to an area where the first emission electrode 171, the light emitting layer 172, and the second emission electrode 173 are sequentially stacked, and holes from the first emission electrode 171 are combined with electrons from the second emission electrode 173 to emit light.

The light emitting layer 172 may be disposed on the first emission electrode 171 and the bank 190. The light emitting layer 172 may include an organic material to emit light of a desired color (e.g., a predetermined color). For example, the light emitting layer 172 may include a hole transporting layer, an organic material layer, and an electron transporting layer.

The second emission electrode 173 may be disposed on the light emitting layer 172. The second emission electrode 173 may be formed to cover the light emitting layer 172. The second emission electrode 173 may be a common layer that is commonly formed over a plurality of light emission areas EA. Additionally, a capping layer may be further formed on the second emission electrode 173.

In the top emission structure, the second emission electrode 173 may be formed of a transparent conductive material that is light-transmittable, for example, such as ITO or IZO, or may be formed of a semi-transmissive conductive material, for example, such as magnesium (Mg), silver (Ag), or an alloy of magnesium (Mg) and silver (Ag). When the second emission electrode 173 is formed of the semi-transmissive conductive material, light emission efficiency may be increased by micro cavities.

An encapsulation layer TFE may be formed on the second emission electrode 173. The encapsulation layer TFE may include at least one inorganic layer to prevent or substantially prevent oxygen and/or moisture from penetrating into the light emitting element layer 172. Further, the encapsulation layer TFE may include at least one organic layer to protect the light emitting element layer 172 from foreign matter, for example, such as dust. For example, the encapsulation layer TFE may include a first inorganic layer TFE1, an organic layer TFE2, and a second inorganic layer TFE3.

The first inorganic layer TFE1 may be disposed on the second emission electrode 173, the organic layer TFE2 may be disposed on the first inorganic layer TFE1, and the second inorganic layer TFE3 may be disposed on the organic layer TFE2. Each of the first inorganic layer TFE1 and the second inorganic layer TFE3 may be formed to have a multi-layered structure in which two or more inorganic layers from among a silicon nitride layer, a silicon oxynitride layer, a silicon oxide layer, a titanium oxide layer, and/or an aluminum oxide layer are alternatively stacked. The organic layer TFE2 may be a monomer layer.

The collimator layer 420 illustrated in FIG. 3 may have an angle (e.g., a cut-off angle), and transmittance characteristics of the light incident on the openings OA. Noise light incident on the photo-sensing element through the openings OA may be reduced or minimized as the angle of the light decreases, and sensing characteristics of the photo-sensing element may increase as transmittance increases.

In order to decrease the angle of light of the collimator layer 420, and increase the transmittance of the collimator layer 420, the thickness of a transmission pattern constituting (e.g., forming) the opening OA may be increased. However, generally, when the thickness of the transmission pattern formed of an organic layer increases, film adhesion may be difficult to maintain due to an increase in the amount of outgas, and uniformity of the thickness may be difficult to secure, so that an uneven pattern may be formed due to a difference in exposure focus.

Hereinafter, a fingerprint sensor capable of reducing the angle of light of the collimator layer 420, and increasing the transmittance of the collimator 420 will be described in more detail.

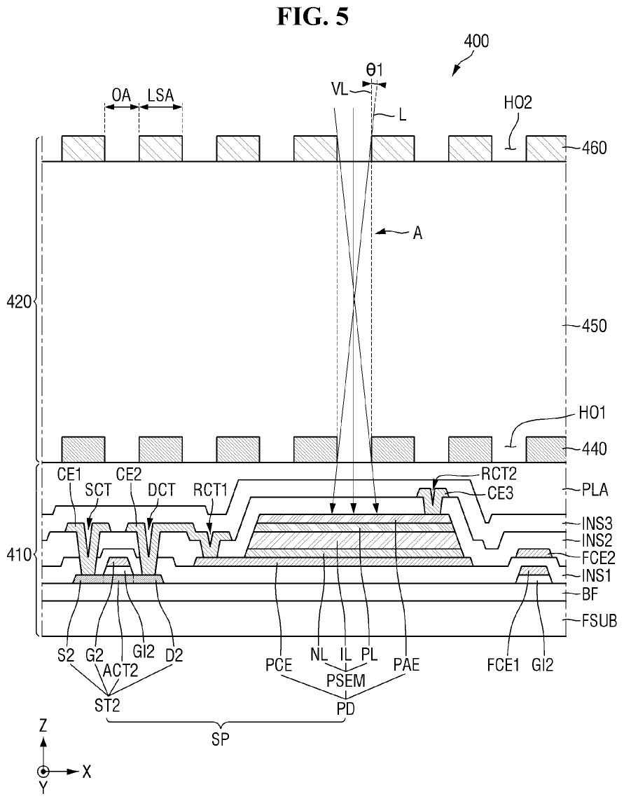

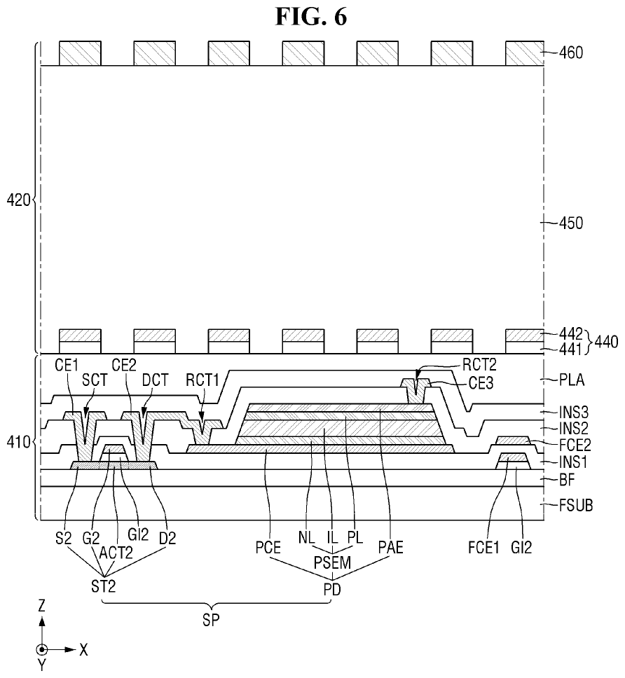

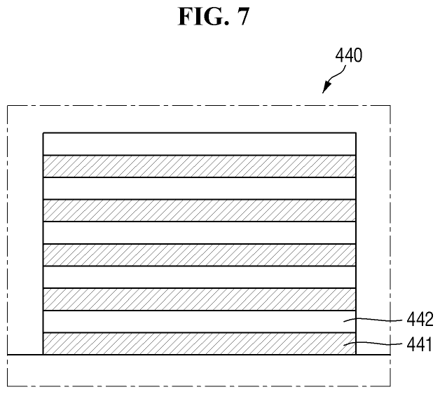

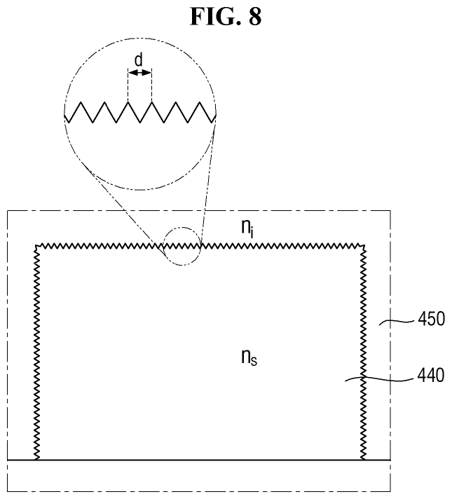

FIG. 5 is a cross-sectional view illustrating an example of a fingerprint sensor according to an embodiment. FIG. 6 is a cross-sectional view illustrating another example of a fingerprint sensor according to an embodiment. FIG. 7 is a cross-sectional view illustrating an example of a first light blocking layer of a fingerprint sensor according to an embodiment. FIG. 8 is a cross-sectional view illustrating another example of a first light blocking layer of a fingerprint sensor according to an embodiment.

Referring to FIG. 5, the fingerprint sensor 400 according to an embodiment may include a fingerprint sensing layer 410, and a collimator layer 420 disposed on the fingerprint sensing layer 410.

The fingerprint sensing layer 410 may include a plurality of sensor pixels SP for sensing light. Each of the sensor pixels SP may include a second thin film transistor ST2, and a photo-sensing element PD.

A buffer layer BF may be disposed on a fingerprint sensor substrate FSUB. The fingerprint sensor substrate FSUB may include (e.g., may be made of) an insulating material, for example, such as a polymer resin. For example, the fingerprint sensor substrate FSUB may include polyimide. The fingerprint sensor substrate FSUB may be a flexible substrate capable of being bent, folded, rolled, and/or the like.

The buffer layer BF may be a layer for protecting the thin film transistor and photo-sensing element PD of the fingerprint sensing layer 410 from moisture penetrating through the fingerprint sensor substrate FSUB, which may be vulnerable to moisture permeation. The buffer layer BF may be formed of a plurality of inorganic layers that are alternately stacked. For example, the buffer layer BF may be formed to have a multi-layered structure in which two or more inorganic layers from among a silicon nitride layer, a silicon oxynitride layer, a silicon oxide layer, a titanium oxide layer, and/or an aluminum oxide layer are alternatively stacked.

A second active layer ACT2 of the second thin film transistor ST2 may be disposed on the buffer layer BF. The second active layer ACT2 of the second thin film transistor ST2 may include polycrystalline silicon, single crystal silicon, low-temperature polycrystalline silicon, amorphous silicon, or an oxide semiconductor. Because the second active layer ACT2 of the second thin film transistor ST2, which may be exposed without being covered by a second gate insulating layer GI2, is doped with impurities or ions, the second active layer ACT2 may have a conductivity. Therefore, conductive regions of the second active layer ACT2 may be formed into a second source electrode S2 and a second drain electrode D2 of the second thin film transistor ST2.

The second gate insulating layer GI2 may be disposed on the second active layer ACT2 of the second thin film transistor ST2. Although FIG. 5 shows that the second gate insulating layer GI2 is disposed between a second gate electrode G2 and the second active layer ACT2 of the second thin film transistor ST2, and between a first fingerprint capacitor electrode FCE1 and the buffer layer BF, the present disclosure is not limited thereto. For example, the second gate insulating layer GI2 may also be disposed between the first insulating layer INS1 and the second active layer ACT2, and between the first insulating layer INS1 and the buffer layer BF. The second gate insulating layer GI2 may be formed of an inorganic layer, for example, such as a silicon nitride layer, a silicon oxynitride layer, a silicon oxide layer, a titanium oxide layer, or an aluminum oxide layer.

The second gate electrode G2 of the second thin film transistor ST2 and the first fingerprint capacitor electrode FCE1 may be disposed on the second gate insulating layer GI2. The second gate electrode G2 of the second thin film transistor ST2 may overlap with the second active layer ACT2 in the third direction (Z-axis direction). The second gate electrode G2 of the second thin film transistor ST2 and the first fingerprint capacitor electrode FCE1 may be formed as a single layer or as multiple layers, including any one or more of molybdenum (Mo), aluminum (Al), chromium (Cr), gold (Au), titanium (Ti), nickel (Ni), neodymium (Nd), copper (Cu), and/or an alloy thereof.

The first insulating layer INS1 may be disposed on the second gate electrode G2 of the second thin film transistor ST2 and the first fingerprint capacitor electrode FCE1. The first insulating layer INS1 may be formed of an inorganic layer, for example, such as a silicon nitride layer, a silicon oxynitride layer, a silicon oxide layer, a titanium oxide layer, or an aluminum oxide layer. The first insulating layer INS1 may include a plurality of inorganic layers.

The photo-sensing element PD and a second fingerprint capacitor electrode FCE2 may be disposed on the first insulating layer INS1. The second fingerprint capacitor electrode FCE2 may overlap with the first fingerprint capacitor electrode FCE1 in the third direction (Z-axis direction). Because the first insulating layer INS1 may have a suitable dielectric constant (e.g., a predetermined dielectric constant), a capacitor may be formed by the first fingerprint capacitor electrode FCE1, the second fingerprint capacitor electrode FCE2, and the first insulating layer INS1 disposed therebetween.

The photo-sensing element PD may be formed as a photodiode as shown in FIG. 5, but the present disclosure is not limited thereto. For example, the photo-sensing element PD may be formed as a phototransistor. The photo-sensing element PD may include a first sensing electrode PCE, a sensing semiconductor layer PSEM, and a second sensing electrode PAE. The first sensing electrode PCE may be a cathode electrode, and the second sensing electrode PAE may be an anode electrode.

The first sensing electrode PCE may be disposed on the first insulating layer INS1. The first sensing electrode PCE may be formed of the same material as that of the second fingerprint capacitor electrode FCE2. Each of the first sensing electrode PCE and the second fingerprint capacitor electrode FCE2 may be formed as a single layer including molybdenum (Mo), titanium (Ti), copper (Cu), or aluminum (Al), or may be formed as a stacked structure of aluminum and titanium (e.g., Ti/Al/Ti), a stacked structure of aluminum and ITO (e.g., ITO/Al/ITO), an APC alloy, or a stacked structure of an APC alloy and ITO (e.g., ITO/APC/ITO).

A light-receiving semiconductor layer PSEM may be disposed on the first sensing electrode PCE. The light-receiving semiconductor layer PSEM may be formed as a PIN structure in which a P-type semiconductor layer PL, an I-type semiconductor layer IL, and an N-type semiconductor layer NL are sequentially stacked. When the light-receiving semiconductor layer PSEM is formed as the PIN structure, the I-type semiconductor layer IL is depleted by the P-type semiconductor layer PL and the N-type semiconductor layer NL, so that an electric field is formed therein, and holes and electrons generated by solar light are drifted by the electric field. Thus, the holes may be collected into the second sensing electrode PAE through the P-type semiconductor layer PL, and the electrons may be collected into the first sensing electrode PCE through the N-type semiconductor layer NL.

The P-type semiconductor layer PL may be disposed to be closer to a surface on which the external light is incident, and the N-type semiconductor layer NL may be disposed to be farther away from the surface on which the external light is incident. Because a drift mobility of the holes is lower than a drift mobility of the electrons, the P-type semiconductor layer PL may be formed to be closer to the incident surface of the external light in order to increase or maximize the collection efficiency of the incident light.

The N-type semiconductor layer NL may be disposed on the first sensing electrode PCE, the I-type semiconductor layer IL may be disposed on the N-type semiconductor layer NL, and the P-type semiconductor layer PL may be disposed on the I-type semiconductor layer IL. In this case, the P-type semiconductor layer PL may be formed by doping amorphous silicon (a-Si:H) with a P-type dopant. The I-type semiconductor layer IL may include (e.g., may be made of) amorphous silicon germanium (a-SiGe:H) or amorphous silicon carbide (a-SiC:H). The N-type semiconductor layer NL may be formed by doping amorphous silicon germanium (a-SiGe:H) or amorphous silicon carbide (a-SiC:H) with an N-type dopant. Each of the P-type semiconductor layer PL and the N-type semiconductor layer NL may be formed to have a thickness of about 500 Å, and the I-type semiconductor layer IL may be formed to have a thickness of 5,000 Å to 10,000 Å.

As another example, the N-type semiconductor layer NL may be disposed on the first sensing electrode PCE, the I-type semiconductor layer IL may be omitted, and the P-type semiconductor layer PL may be disposed on the N-type semiconductor layer NL. In this case, the P-type semiconductor layer PL may be formed by doping amorphous silicon (a-Si:H) with a P-type dopant. The N-type semiconductor layer NL may be formed by doping amorphous silicon germanium (a-SiGe:H) or amorphous silicon carbide (a-SiC:H) with an N-type dopant. Each of the P-type semiconductor layer PL and the N-type semiconductor layer NL may be formed to have a thickness of about 500 Å.

An upper or lower surface of at least one of the first sensing electrode PCE, the P-type semiconductor layer PL, the I-type semiconductor layer IL, the N-type semiconductor layer NL, and/or the second sensing electrode PAE may be formed to have an uneven structure through a texturing process in order to increase an absorption rate of the external light. The texturing process is a process of forming the surface of a suitable material to have a roughly uneven structure, and is a process of texturizing the surface thereof to have the same or substantially the same shape as that of the surface of a fabric. The texturing process may be performed through an etching process using photolithography, an anisotropic etching process using a chemical solution, or a groove forming process using mechanical scribing.

The second sensing electrode PAE may be disposed on the P-type semiconductor layer PL. The second sensing electrode PAE may be formed of a light-transmittable transparent conductive material TCO, for example, such as indium tin oxide (ITO) or indium zinc oxide (IZO).

A second insulating layer INS2 may be disposed on the photo-sensing element PD and the second fingerprint capacitor electrode FCE2. The second insulating layer INS2 may be formed of an inorganic layer, for example, such as a silicon nitride layer, a silicon oxynitride layer, a silicon oxide layer, a titanium oxide layer, or an aluminum oxide layer. The second insulating layer INS2 may include a plurality of inorganic layers.

A first connection electrode CE1, a second connection electrode CE2, and a third connection electrode CE3 may be disposed on the second insulating layer INS2.

The first connection electrode CE1 may be connected to the second source electrode S2 of the second thin film transistor ST2 through a source contact hole SCT that penetrates the first insulating layer INS1 and the second insulating layer INS2 to expose the second source electrode S2 of the second thin film transistor ST2.

The second connection electrode CE2 may be connected to the second drain electrode D2 of the second thin film transistor ST2 through a drain contact hole DCT that penetrates the first insulating layer INS1 and the second insulating layer INS2 to expose the second drain electrode D2 of the second thin film transistor ST2. The second connection electrode CE2 may also be connected to the first sensing electrode PCE through a first sensing contact hole RCT1 that penetrates the second insulating layer INS2 to expose the first sensing electrode PCE. Accordingly, the drain electrode D2 of the second thin film transistor ST2 may be connected to the first sensing electrode PCE of the photo-sensing element PD by the second connection electrode CE2.

The third connection electrode CE3 may be connected to the second sensing electrode PAE through a second sensing contact hole RCT2 that penetrates the second insulating layer INS2 to expose the second sensing electrode PAE.

Each of the first connection electrode CE1, the second connection electrode CE2, and the third connection electrode CE3 may be formed as a single layer or as multiple layers, including any one or more of molybdenum (Mo), aluminum (Al), chromium (Cr), gold (Au), titanium (Ti), nickel (Ni), neodymium (Nd), copper (Cu), and/or an alloy thereof.

A third insulating layer INS3 may be disposed on the first connection electrode CE1, the second connection electrode CE2, and the third connection electrode CE3. The third insulating layer INS3 may be formed of an inorganic layer, for example, such as a silicon nitride layer, a silicon oxynitride layer, a silicon oxide layer, a titanium oxide layer, or an aluminum oxide layer. The third insulating layer INS3 may include a plurality of inorganic layers. However, the present disclosure is not limited thereto, and the third insulating layer INS3 may be omitted.

A planarization layer PLA may be disposed on the third insulating layer INS3. The planarization layer PLA may be formed of an organic material, for example, such as acrylic resin, epoxy resin, phenolic resin, polyamide resin, and/or polyimide resin.

The collimator layer 420 may include a first light blocking layer 440, a first light transmitting layer 450, and a second light blocking layer 460.

The first light blocking layer 440 may be disposed on the light sensing layer 410. The light blocking layer 440 may include a plurality of first holes HO1, and may be entirely disposed on the light sensing layer 410.

The first light blocking layer 440 may include (e.g., may be made of) a low-reflectance material capable of blocking or absorbing light. The first light blocking layer 440 may have a single-layer structure. For example, the first light blocking layer 440 may include a black matrix or amorphous carbon (aC:H) including an inorganic black pigment, for example, such as carbon black, or an organic black pigment.

The width of the first light blocking layer 440 may be approximately 1 μm to 1.5 μm, but is not limited thereto. The width of the first light blocking layer 440 may be a length thereof in the first direction (X-axis direction), or a length thereof in the second direction (Y-axis direction), between the plurality of first holes HO1.

The first light transmitting layer 450 may be disposed on the light sensing layer 410 and the first light blocking layer 440. The first light transmitting layer 450 may be entirely disposed on the light sensing layer 410 and the first light blocking layer 440. The first light transmitting layer 450 may cover the first light blocking layer 440, and may be formed to be flat or substantially flat on a surface of the first light blocking layer 440. The first light transmitting layer 450 may fill the plurality of first holes HO1 in the first light blocking layer 440, and may contact the upper surface of the light sensing layer 410.

The thickness of the first light transmitting layer 450 in the third direction (Z-axis direction) may be 5 μm or more. For example, the thickness of the first light transmitting layer 450 may be 10 μm or more. In an embodiment, the first light transmitting layer 450 may be formed entirely, thereby preventing or substantially preventing the deterioration of adhesive properties due to a thick thickness.

The first light transmitting layer 450 may be formed of a transparent organic material capable of transmitting light. For example, the first light transmitting layer 450 may be formed of acrylic resin, epoxy resin, phenolic resin, polyamide resin, or polyimide resin.

The second light blocking layer 460 may be disposed on the first light transmitting layer 450. The second light blocking layer 460 may include a plurality of second holes HO2, and may be entirely disposed on the first light transmitting layer 450. The second holes HO2 of the second light blocking layer 460 may be arranged to overlap with the first holes HO1 of the first light blocking layer 440, respectively.

The second light blocking layer 460 may include (e.g., may be made of) a low-reflectance material capable of blocking or absorbing light. The second light blocking layer 460 may have a single-layer structure. Unlike the first light blocking layer 440, the second light blocking layer 460 may include a metal, so that a fine pattern may be formed thereof. For example, the second light blocking layer 460 may include a metal, for example, such as chromium (Cr), molybdenum (Mo), tungsten (W), titanium (Ti), or cobalt (Co).

The width of the second light blocking layer 460 may be approximately 1 μm to 1.5 μm, but is not limited thereto. The width of the second light blocking layer 460 may be a length in the first direction (X-axis direction), or a length in the second direction (Y-axis direction), between the plurality of second holes HO2.

Each of the openings OA of the collimator layer 420 may be defined as a region where the first light blocking layer 440 and the second light blocking layer 460 are not disposed in the third direction (Z-axis direction), and the light blocking portion LSA of the collimator layer 420 may be defined as a region where the first and second light blocking layers 440 and 460 are disposed. Each of the openings OA may be defined as a region where a corresponding first hole HO1 overlaps with a corresponding second hole HO2, and the light blocking portion LSA may be defined as a region where the first light blocking layer 440 overlaps with the second light blocking layer 460. Because the photo-sensing element PD overlaps with a plurality of openings OA from among the openings OA in the third direction (Z-axis direction), light may be incident on the photo-sensing element PD of the sensor pixel SP through the openings OA.

The width of each of the openings OA of the collimator layer 420 may be equal to the diameter of the corresponding first hole HO1 and the corresponding second hole HO2. In an embodiment, in order to increase the aperture ratio of the collimator layer 420, the width of the opening OA may be 2 μm or more. In other words, each of the corresponding first hole HO1 and the corresponding second hole HO2 may have a diameter of 2 μm or more.

FIG. 5 shows a path of light incident on the opening OA of the collimator layer 420. Light incident through the opening OA may be incident on the photo-sensing element PD of the light sensing layer 410. Light that is incident on the opening OA and having an angle of light that is equal to or less than a first angle 81 may pass through the opening OA. The angle of light incident on the opening OA may be an angle that is inclined from a normal line VL extending perpendicularly or substantially perpendicularly from an upper surface (e.g., from the upper surface of the first light transmitting layer 450) in the opening OA.

In an embodiment, the first light blocking layer 440 and the second light blocking layer 460 may be disposed to be spaced apart from each other with the first light transmitting layer 450 therebetween. Thus, an aspect ratio of an area A of the first light transmitting layer 450 corresponding to the incident path of the light may be formed to be 7:1 or more by increasing the thickness of the first light transmitting layer 450. Therefore, the first angle 81 of light passing through the opening OA and incident on the photo-sensing element PD may be 10° or less, thereby reducing or minimizing the noise light.

Further, the first light transmitting layer 450 may be entirely formed to omit a pattern of the first light transmitting layer, thereby enabling the forming of the light blocking layers having a finer pattern. Accordingly, the transmittance of light may be improved by increasing the width of the opening OA.

According to an embodiment, the first light blocking layer 440 may have a multi-layered structure.

Referring to FIG. 6, the first light blocking layer 440 may include a first layer 441, and a second layer 442 disposed on the first layer 441. The first layer 441 may include a metal. For example, the metal may be any suitable one selected from among aluminum (Al), molybdenum (Mo), chromium (Cr), tungsten (W), titanium (Ti), silver (Ag), nickel (Ni), cobalt (Co), and/or copper (Cu). The second layer 442 may include a metal oxide. For example, the metal oxide may be any suitable one selected from among molybdenum oxide (MoOx), copper oxide (CuOx), and/or graphene oxide (GO). In an embodiment, the first light blocking layer 440 may have a structure in which the first layer 441 including (e.g., made of) molybdenum (Mo) and the second layer 442 including (e.g., made of) molybdenum oxide (MoOx) are stacked. However, the present disclosure is not limited thereto, and the first light blocking layer 440 may have a structure in which three or more layers are stacked. For example, the first light blocking layer 440 may be formed of three layers in which titanium (Ti), copper (Cu), and graphene (GO) are sequentially stacked.

When light is incident on the first light blocking layer 440 having the multi-layered structure, a portion of the light is absorbed by the second layer 442, and the remaining light may be destructively interfered with to exhibit low-reflection characteristics.

Referring to FIG. 7, in an embodiment, the first light blocking layer 440 may have a multi-layered structure in which a plurality of layers having different refractive indices from one another are alternately stacked with each other. In the first light blocking layer 440, first layers 441 and second layers 442 having smaller refractive indices than those of the first layers 441 may be alternately stacked with each other. In the first light blocking layer 440, the first layer 441 having a relatively larger refractive index may be disposed at the bottom of the first light blocking layer 440, and the second layer 442 having a relatively smaller refractive index may be disposed on the first layer 441. Light reflected from each of the layers may be destructively interfered with to reduce the reflection of light.

In an embodiment, the first light blocking layer 440 may be formed as a stacked structure of alternately stacked oxide layers. The oxide layer may include at least one selected from among titanium oxide (TiOx), silicon nitride (SiNx), silicon oxide (SiOx), tantalum oxide (TaxOy), and/or silicon nitride oxide (SiON). In the first light blocking layer 440, from among the oxide layers, layers having relatively larger refractive indices may be provided as the first layers 441, layers having relatively smaller refractive indices may be provided as the second layers 442, and these layers may be alternately stacked with each other. In an embodiment, in the first light blocking layer 440, the first layers 441 including (e.g., made of) titanium oxide (TiOx) and the second layers 442 including (e.g., made of) silicon oxide (SiOx) may be alternately stacked with each other. Further, in the first light blocking layer 440, the first layers 441 including (e.g., made of) silicon nitride (SiNx) and the second layers 442 including (e.g., made of) silicon oxide (SiOx) may be alternately stacked with each other.

Although FIG. 7 shows that the first layers 441 and the second layers 442 are alternately stacked with each other to form a stacked structure of ten layers, the present disclosure is not limited thereto, and the first layers 441 and the second layers 442 may be alternately stacked with each other to form a stacked structure of ten or more layers.

In an embodiment, the first light blocking layer 440 may have a single layer structure, but may have a structure capable of reducing the reflection of light by destructive interference with the light.

Referring to FIG. 8, the first light blocking layer 440 may have a moth eye structure. The moth eye structure may refer to a structure including a plurality of irregularities arranged at intervals that are less than or equal to a visible light wavelength, which may not reflect light at all regardless of the incident angle or wavelength of the light. The moth eye structure may have an uneven structure having a suitable shape, for example, such as a square pyramid or cone.

The first light blocking layer 440 may have the moth eye structure on the upper surface thereof, or on the upper and side surfaces thereof. For convenience of illustration, FIG. 8 shows that the first light blocking layer 440 has the moth eye structure on the upper and side surfaces thereof. When visible light is incident on the moth eye structure including a plurality of irregularities formed at intervals d that are less than or equal to the visible light wavelength, and having a refractive index ns that is greater than the refractive index ni of air, the incident light travels in the same or substantially the same path as that of light that is incident on a medium having a refractive index that continuously changes from ni to ns. Accordingly, when light is incident on the first light blocking layer 440 having the refractive index that is continuously changed, Fresnel reflection may not occur, and thus, reflectance may be reduced.

As described above, in one or more embodiments, the first light blocking layer 440 and the second light blocking layer 460 may be disposed to be spaced apart from each other with the first light transmitting layer 450 therebetween. Accordingly, the aspect ratio of the area A of the first light transmitting layer 450 corresponding to the incident path of light may be formed to be 7:1 or more by increasing the thickness of the first light transmitting layer 450. Therefore, the first angle θ1 of light passing through the opening OA and incident on the photo-sensing element PD may be 10° or less, thereby reducing or minimizing the noise light.

Further, the first light transmitting layer 450 may be entirely formed to omit a pattern of the first light transmitting layer, thereby enabling the forming of the light blocking layers having a finer pattern. Accordingly, the transmittance of light may be improved by increasing the width of the opening OA.

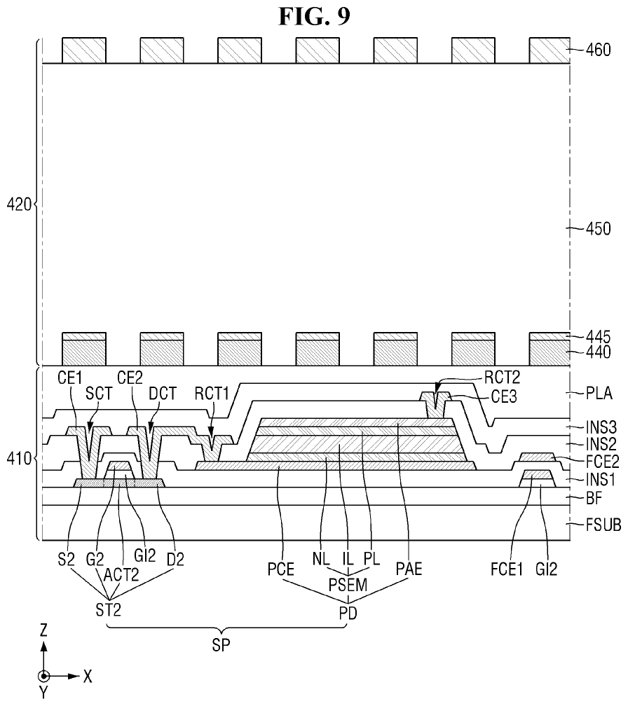

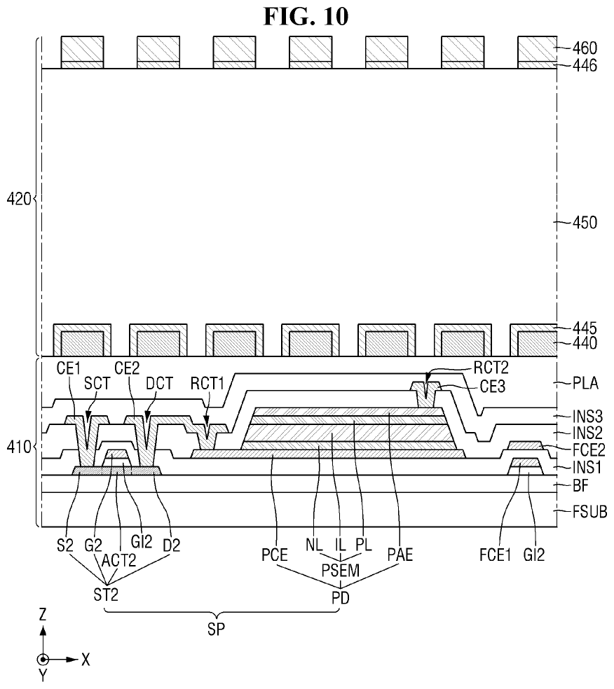

FIG. 9 is a cross-sectional view illustrating an example of a fingerprint sensor according to another embodiment. FIG. 10 is a cross-sectional view illustrating another example of a fingerprint sensor according to another embodiment.

Referring to FIG. 9, the fingerprint sensor according to the present embodiment may be different from the fingerprint sensor of the embodiments described above with reference to FIGS. 5 to 8, in that the first light blocking layer 440 and the second light blocking layer 460 may include (e.g., may be made of a metal), and the fingerprint sensor further includes a first antireflection layer or a second antireflection layer. Hereinafter, the differences in the embodiment of FIG. 9 may be mainly described in more detail, and redundant description may not be repeated.

The collimator layer 420 of the fingerprint sensor 400 according to the present embodiment may include the first light blocking layer 440, a first antireflection layer 445, the first light transmitting layer 450, and the second light blocking layer 460.

Unlike those of the embodiments described above, the first light blocking layer 440 may include (e.g., may be made of) a metal capable of blocking light. For example, the metal may include any suitable one selected from among aluminum (Al), molybdenum (Mo), chromium (Cr), tungsten (W), titanium (Ti), silver (Ag), nickel (Ni), cobalt (Co), and/or copper (Cu).

The first antireflection layer 445 may be disposed on the first light blocking layer 440. The first anti-reflection layer 445 may serve to prevent or substantially prevent light from being reflected from the first light blocking layer 440 including (e.g., made of) the metal. The first antireflection layer 445 may be disposed between the first light blocking layer 440 and the first light transmitting layer 450, and may be in contact with the upper surface of the first light blocking layer 440 and the first light transmitting layer 450.

The first antireflection layer 445 may include (e.g., may be made of) a low-reflectance material capable of blocking or absorbing light. The first antireflection layer 445 may be formed of the same material as that of the first light blocking layer 440 described above with reference to FIGS. 5 to 8. For example, the first antireflection layer 445 may include a black matrix or amorphous carbon, a stacked structure of a metal and a metal oxide, an alternately stacked structure of a plurality of oxide layers having different refractive indices from each other, or a moth eye structure.

In an embodiment, when the first light blocking layer 440 includes (e.g., is made of) the metal, the first antireflection layer 445 may be further formed to block light incident on the collimator layer 420.

Referring to FIG. 10, the first antireflection layer 445 may completely cover the first light blocking layer 440. In an embodiment, the first antireflection layer 445 may be disposed to contact the upper and side surfaces of the first light blocking layer 440 to cover the first light blocking layer 440. Accordingly, it may be possible to prevent or substantially prevent light from being reflected from the side surfaces of the first light blocking layer 440, and acting as the noise light.

In an embodiment, a second antireflection layer 446 may be further provided under (e.g., underneath) the second light blocking layer 460. The second antireflection layer 446 may be disposed between the second light blocking layer 460 and the first light transmitting layer 450, and may be in contact with the lower surface of the second light blocking layer 460 and the upper surface of the first light transmitting layer 450. The second antireflection layer 446 and the first antireflection layer 445 may be disposed to overlap with each other. The second antireflection layer 446 may include (e.g., may be made of) the same material as that of the above-described first antireflection layer 445.

The second antireflection layer 446 may prevent or substantially prevent the light reflected in the collimator layer 420 from being re-reflected under the second light blocking layer 460, thereby preventing or substantially preventing the reflected light from acting as the noise light.

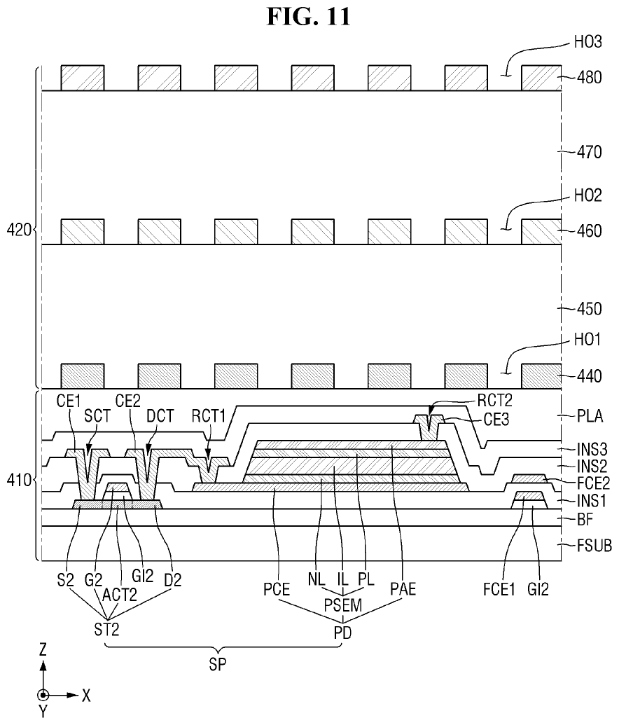

FIG. 11 is a cross-sectional view illustrating an example of a fingerprint sensor according to another embodiment.

Referring to FIG. 11, the fingerprint sensor according to the present embodiment may be different from the fingerprint sensor of the embodiments described above with reference to FIGS. 5 to 8, in that the fingerprint sensor may further include a second light transmitting layer 470 and a third light blocking layer 480. Hereinafter, the differences in the embodiment of FIG. 11 may be mainly described in more detail, and redundant description may not be repeated.

The collimator layer 420 of the fingerprint sensor 400 according to the present embodiment may include the first light blocking layer 440, the first light transmitting layer 450, the second light blocking layer 460, the second light transmitting layer 470, and the third light blocking layer 480.

The second light transmitting layer 470 may be disposed on the second light blocking layer 460 and the first light transmitting layer 450. The second light transmitting layer 470 may be formed of the same material as that of the above-described first light transmitting layer 450, and may have the same or substantially the same thickness as that of the above-described first light transmitting layer 450. However, the present disclosure is not limited thereto, and the thickness of the second light transmitting layer 470 may be smaller than or greater than the thickness of the first light transmitting layer 450.

The third light blocking layer 480 may be disposed on the second light transmitting layer 470. The third light blocking layer 480 may include (e.g., may be made of) a metal material capable of blocking light, and may include (e.g., may be made of) the same material as that of the above-described second light blocking layer 460. The third light blocking layer 480 may be disposed to overlap with the first light blocking layer 440 and the second light blocking layer 460. The third light blocking layer 480 includes a plurality of third holes HO3, and each of the third holes HO3 may be disposed to overlap with a corresponding first hole HO1 of the first light blocking layer 440 and a corresponding second hole HO2 of the second light blocking layer 460.

In an embodiment, the second light transmitting layer 470 and the third light blocking layer 480 may be disposed on the first light transmitting layer 450, thereby increasing the thickness of the collimator layer 420. Accordingly, the first angle 81 of light passing through the opening OA and incident on the photo-sensing element PD may be 10° or less, thereby reducing or minimizing the noise light.

Although FIG. 11 shows that the second light transmitting layer 470 and the third light blocking layer 480 are formed, the present disclosure is not limited thereto, and a light transmitting layer and a light blocking layer may be further stacked on the third light blocking layer 480. Further, in some embodiments, the first light blocking layer 440, the second light blocking layer 460, and/or the third light blocking layer 480 may further include the above-described antireflection layer as shown in FIG. 9 or 10.

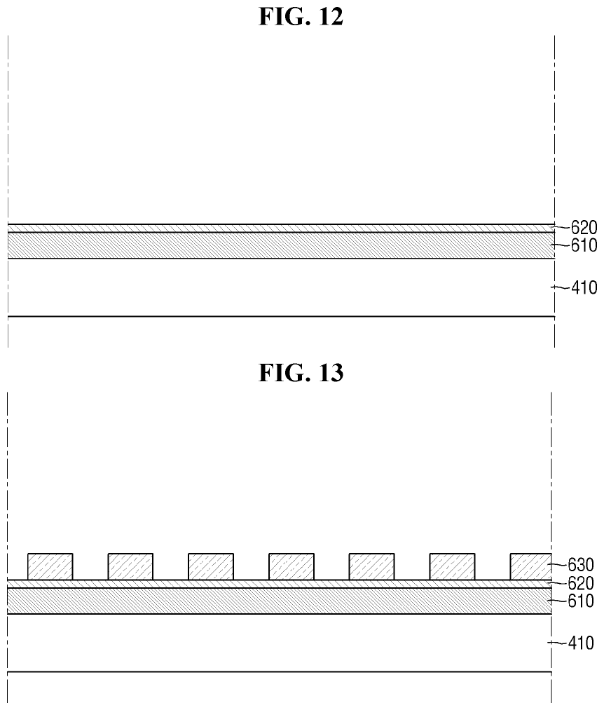

FIGS. 12 to 16 are cross-sectional views illustrating various processes of a method of manufacturing the fingerprint sensor of FIG. 9. FIG. 17 is a cross-sectional view illustrating another example of a method of manufacturing the fingerprint sensor of FIG. 9. Hereinafter, the structure of the light sensing layer 410 shown in FIG. 9 may be briefly described or redundant description thereof may not be repeated, and a method of manufacturing the collimator layer 420 will be described in more detail.

Referring to FIG. 12, a first light blocking material layer 610 is stacked on the photo-sensing layer 410, and a first antireflective material layer 620 is stacked on the first light blocking material layer 610. The first light blocking material layer 610 may include a metallic material. The first antireflective material layer 620 may include a black matrix or amorphous carbon, a stacked structure of a metal and a metal oxide, an alternately stacked structure of a plurality of oxide layers having different refractive indices from each other, or a moth eye structure.

Referring to FIG. 13, an organic material or an inorganic material is applied onto the first antireflective material layer 620 to form a first mask pattern 630. The first mask pattern 630 may be an organic layer, for example, such as a photoresist. As another example, the first mask pattern 630 may be an inorganic layer including a transparent conductive oxide (TCO), for example, such as indium tin oxide (ITO) or indium zinc oxide (IZO).

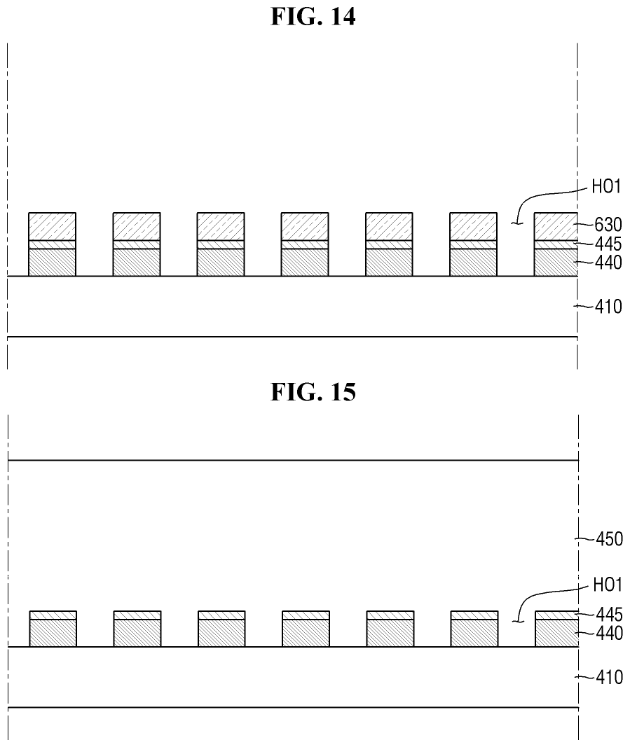

Referring to FIG. 14, the first light blocking material layer 610 and the first antireflective material layer 620, which are covered by the first mask pattern 630, are etched to form a first light blocking layer 440 and a first antireflection layer 445. A plurality of first holes HO1 are formed in the first light blocking layer 440. The light blocking layer 440 and the first antireflection layer 445 may be disposed to overlap with each other.

Referring to FIG. 15, the first mask pattern 630 is removed by a stripping process or an etching process. An organic material is applied onto the light sensing layer 410 including the first light blocking layer 440 and the first antireflection layer 445 to form a first light transmitting layer 450. The first light transmitting layer 450 is formed to cover the first light blocking layer 440 and the first antireflection layer 445. The first light transmitting layer 450 may be an organic layer including an acrylic resin, an epoxy resin, a phenolic resin, a polyamide resin, or a polyimide resin.

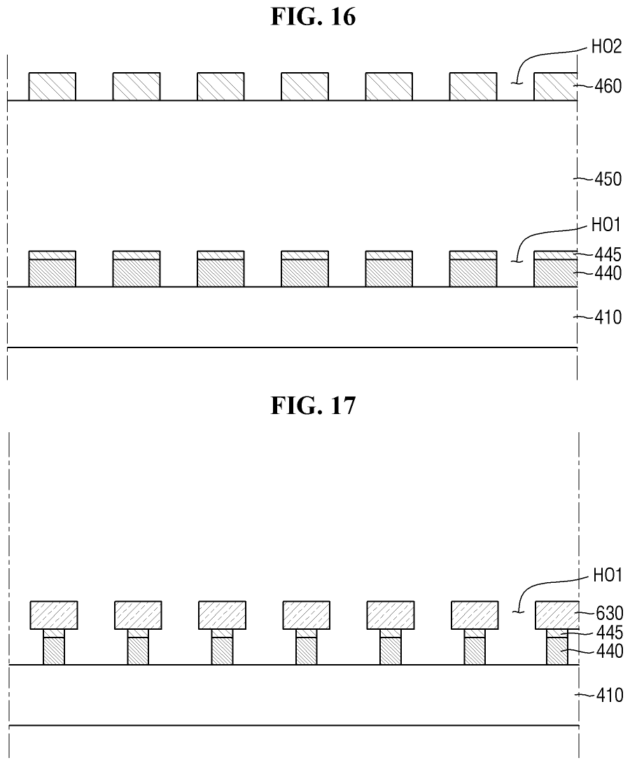

Referring to FIG. 16, a metal is applied onto the first light transmitting layer 450, and the metal is patterned by an etching process that is the same or substantially the same as (or similar to) those described with reference to FIGS. 13 and 14 to form a second light blocking layer 460 including a plurality of second holes HO2, thereby manufacturing the collimator layer 420.

While the first mask pattern 630 has been described as an organic layer or an inorganic layer, the present disclosure is not limited thereto, and for example, the mask pattern 630 may include (e.g., may be made of) a metal.

Referring to FIG. 17, when the first mask pattern 630 is formed of a metal, the first light blocking layer 440 and first antireflection layer 445 under (e.g., underneath) the first mask pattern 630 may be further etched to have a narrower width as compared to those formed by using the first mask pattern 630 including the organic layer or the inorganic layer. Accordingly, an opening through which light passes may be increased, thereby improving transmittance. Further, because the first mask pattern 630 including (e.g., made of) the metal may function as a mask even with a thin thickness, the first mask pattern 630 may be easily formed.

In the above-described manufacturing method, the collimator layer 420 shown in FIG. 9 has been described as an example. However, the collimator layer 420 shown in FIG. 5 may be formed by omitting the formation of the first antireflection layer.

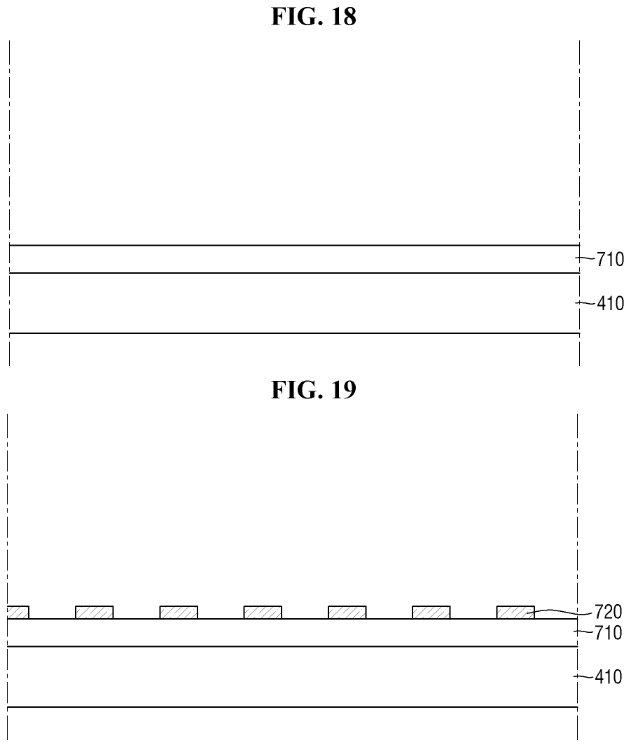

FIGS. 18 to 23 are cross-sectional views illustrating various processes of a method of manufacturing a fingerprint sensor according to another embodiment.

FIGS. 18 to 23 are views illustrating various processes of a method of manufacturing the fingerprint sensor shown in FIG. 5, and a case where the first light blocking layer 440 includes an organic material, for example, such as a black matrix, is described in more detail as an example. Hereinafter, the structure of the light sensing layer 410 shown in FIG. 5 may be briefly described or redundant description thereof may not be repeated, and a method of manufacturing the collimator layer 420 will be described in more detail.

Referring to FIG. 18, a first light transmitting material layer 710 is formed on the light sensing layer 410 by coating. The first light transmitting material layer 710 is an organic layer including an acrylic resin, an epoxy resin, a phenolic resin, a polyamide resin, or a polyimide resin.

Referring to FIG. 19, an organic material or an inorganic material is applied onto the first light transmitting material layer 710 to form a second mask pattern 720. The second mask pattern 720 may be an organic layer, for example, such as a photoresist. As another example, the second mask pattern 720 may be an inorganic layer including a transparent conductive oxide (TCO), for example, such as indium tin oxide (ITO) or indium zinc oxide (IZO).

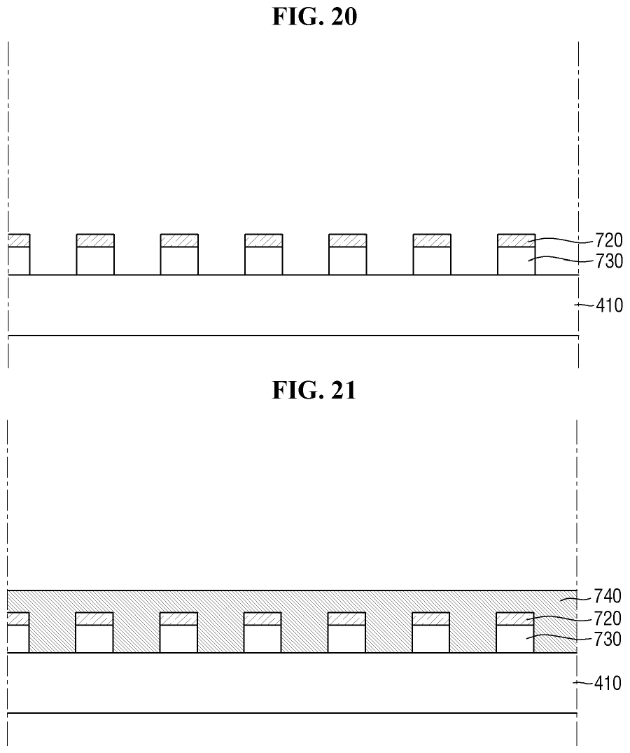

Referring to FIG. 20, portions of the first light transmitting material layer 710 that are not covered by the second mask pattern 720 are etched to form sub-light transmitting layers 730. The sub-light transmitting layers 730 may be disposed to be spaced apart from each other.

Referring to FIG. 21, a first light blocking material layer 740 is stacked on the light sensing layer 410 including the second mask pattern 720 and the sub-light transmitting layers 730. The first light blocking material layer 740 may include a black matrix including (e.g., made of) an organic material. The first light blocking material layer 740 may cover the entire sub-light transmitting layers 730 and second mask pattern 720.

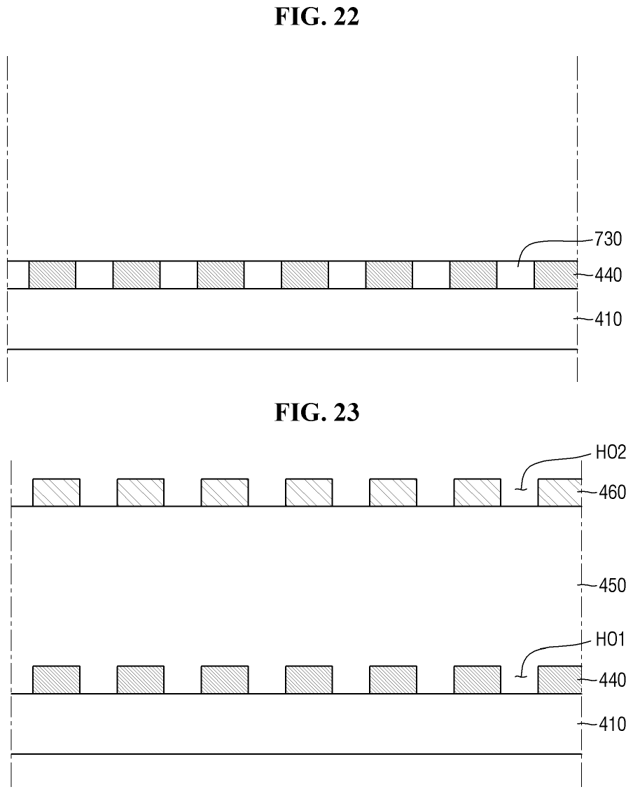

Referring to FIG. 22, the first light blocking material layer 740 and the second mask pattern 720 may be removed using a front polishing process. During the front polishing process, the first light blocking material layer 740 and the second mask pattern 720 are polished to expose the upper surfaces of the sub-light transmitting layers 730, thereby removing the second mask pattern 720 and forming the first light blocking material layer 740 into a first light blocking layer 440 between the sub-light transmitting layers 730. The regions of the sub-light transmitting layer 730 disposed between the first light blocking layer 440 may be a plurality of first holes HO2 of the first light blocking layer 440. In another embodiment, the first light blocking layer 440 may be formed by developing the first light blocking material layer 740, and additionally removing the second mask pattern 720.

Referring to FIG. 23, an organic material is applied onto the light sensing layer on which the sub-light transmitting layers 730 and the first light blocking layer 440 are formed, to form a first light transmitting layer 450. The first light transmitting layer 450 is formed of the same material as that of the above-described sub-light transmitting layer 730, so that the sub-light-transmitting layer 730 may appear as the same layer as that of the first light transmitting layer 450. In another embodiment, when the first light transmitting layer 450 and the sub-light transmitting layer 730 are formed of different materials from each other, the first light transmitting layer 450 and the sub-light transmitting layer 730 may appear as separate layers from each other.

A metal is applied onto the first light transmitting layer 450, and the metal is patterned by an etching process to form a second light blocking layer 460 including a plurality of second holes HO2, thereby manufacturing the collimator layer 420.

As shown in FIGS. 18 to 23, the first light blocking layer 440 may be formed of the black matrix of an organic material by a coating process, thereby simplifying a manufacturing process. Therefore, the efficiency of a process for manufacturing the fingerprint sensor 400 may be increased.

Although FIGS. 12 to 23 illustrate various methods of manufacturing the fingerprint sensor shown in the embodiments of FIGS. 5 and 9, the present disclosure is not limited thereto, and the fingerprint sensor of FIG. 11 may be manufactured by additionally forming the second light transmitting layer 470 and the third light blocking layer 480 on the second light blocking layer 460 using processes that are the same or substantially the same as (or similar to) those of the above-described methods.

As described above, in one or more embodiments, the first light blocking layer 440 and the second light blocking layer 460 may be disposed to be spaced apart from each other with the first light transmitting layer 450 therebetween. Thus, an aspect ratio of the area A of the first light transmitting layer 450 corresponding to the incident path of light may be formed to be 7:1 or more by increasing the thickness of the first light transmitting layer 450. Therefore, the first angle 81 of light passing through the opening OA and incident on the photo-sensing element PD may be controlled to be 10° or less, thereby reducing or minimizing the noise light.

Further, the first light transmitting layer 450 may be entirely formed to omit a pattern of the first light transmitting layer, thereby forming light blocking layers having a finer pattern. Accordingly, the transmittance of light may be improved by increasing the width of the opening OA.

According to a fingerprint sensor of one or more embodiments and a display device including the same, light blocking layers that are spaced apart from each other with a first light transmitting layer therebetween are formed, so that the thickness of the first light transmitting layer may be increased to decrease an angle of light passing through an opening and incident on a photo-sensing element, thereby reducing or minimizing the noise light.

Further, the first light transmitting layer may be entirely formed to form light blocking layers having a finer pattern, thereby increasing the width of the opening to improve transmittance.

However, the present disclosure is not limited to the aspects and features described by the foregoing, and other various aspects and features are included herein.

Although some example embodiments have been described, those skilled in the art will readily appreciate that various modifications are possible in the example embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific example embodiments disclosed herein, and that various modifications to the disclosed example embodiments, as well as other example embodiments, are intended to be included within the spirit and scope of the present disclosure as defined in the appended claims, and their equivalents.

What is claimed is:

1. A fingerprint sensor, comprising:
a light sensing layer comprising a photo-sensing element configured to flow a sensing current according to incident light; and
a collimator layer on the light sensing layer, the collimator layer comprising:
a first light blocking layer having a plurality of first holes;
a first light transmitting layer on the first light blocking layer; and
a second light blocking layer on the first light transmitting layer, and having a plurality of second holes overlapping with the plurality of first holes.

2. The fingerprint sensor of claim 1, wherein the first light transmitting layer fills the plurality of first holes, and covers the first light blocking layer.

3. The fingerprint sensor of claim 1, wherein the first light blocking layer has a single-layer structure or a multi-layered structure.

4. The fingerprint sensor of claim 3, wherein the first light blocking layer has the single-layer structure, and comprises a black matrix or amorphous carbon.

5. The fingerprint sensor of claim 3, wherein the first light blocking layer has the multi-layer structure, and comprises a metal layer and a metal oxide layer that are stacked on one another.

6. The fingerprint sensor of claim 3, wherein the first light blocking layer has the multi-layer structure, and comprises a plurality of oxide layers having different refractive indices from one another that are alternately stacked with each other.

7. The fingerprint sensor of claim 6, wherein the plurality of oxide layers have a stacked structure of silicon oxide and silicon nitride, or a stacked structure of silicon oxide and titanium oxide.

8. The fingerprint sensor of claim 1, wherein the first light blocking layer comprises a moth eye structure on at least one surface thereof.

9. The fingerprint sensor of claim 1, wherein each of the first light blocking layer and the second light blocking layer comprises a metal.

10. The fingerprint sensor of claim 9, further comprising:
a first antireflection layer between the first light blocking layer and the first light transmitting layer.

11. The fingerprint sensor of claim 10, wherein the first antireflection layer contacts at least one of an upper surface or a side surface of the first light blocking layer.

12. The fingerprint sensor of claim 10, further comprising:
a second antireflection layer between the first light transmitting layer and the second light blocking layer.

13. The fingerprint sensor of claim 12, wherein the second antireflection layer contacts a lower surface of the second light blocking layer and the first light transmitting layer.

14. A fingerprint sensor, comprising:
a light sensing layer comprising a photo-sensing element configured to flow a sensing current according to incident light; and
a collimator layer on the light sensing layer, the collimator layer comprising:
a first light blocking layer having a plurality of first holes;
a first light transmitting layer on the first light blocking layer;
a second light blocking layer on the first light transmitting layer, and having a plurality of second holes overlapping with the plurality of first holes;
a second light transmitting layer on the second light blocking layer; and
a third light blocking layer on the second light transmitting layer, and having a plurality of third holes overlapping with the plurality of second holes.

15. The fingerprint sensor of claim 14,
wherein the first light transmitting layer fills the plurality of first holes, and is located on the first light blocking layer, and
wherein the second light transmitting layer fills the plurality of second holes, and is located on the second light blocking layer.

16. The fingerprint sensor of claim 14, wherein the first light blocking layer has a single-layer structure, and comprises a black matrix or amorphous carbon.

17. The fingerprint sensor of claim 14, wherein the first light blocking layer has a single-layer structure, and comprises a moth eye structure on at least one surface thereof.

18. The fingerprint sensor of claim 14,
wherein the first light blocking layer has a multi-layered structure, and
wherein the first light blocking layer comprises a metal layer and a metal oxide layer that are stacked on one another, or a plurality of oxide layers having different refractive indices from one another that are alternately stacked with each other.

19. A display device, comprising:
a display panel configured to display an image; and
a fingerprint sensor on a surface of the display panel, and configured to sense light passed through the display panel,
wherein the fingerprint sensor comprises:
a light sensing layer comprising a photo-sensing element configured to flow a sensing current according to incident light; and
a collimator layer on the light sensing layer, and
wherein the collimator layer comprises:
a first light blocking layer having a plurality of first holes;
a first light transmitting layer on the first light blocking layer; and
a second light blocking layer on the first light transmitting layer, and having a plurality of second holes overlapping with the plurality of first holes.

20. The display device of claim 19, wherein the photo-sensing element comprises:
a first sensing electrode;
a sensing semiconductor layer on the first sensing electrode, and comprising an N-type semiconductor layer, an I-type semiconductor layer, and a P-type semiconductor layer; and
a second sensing electrode on the sensing semiconductor layer.
